(19) United States
(12) Patent Application Publication
(10) Pub. No.: US 2024/0034958 A1
(43) Pub. Date: Feb. 1, 2024

(54) COMPOSITIONS AND METHODS OF USE THEREOF

(71) Applicant: FUJIFILM ELECTRONIC MATERIALS U.S.A., INC., North Kingstown, RI (US)

(72) Inventors: Yannan Liang, Gilbert, AZ (US); Bin Hu, Chandler, AZ (US); Shu-Wei Chang, Taoyuan City (TW)

(73) Assignee: FUJIFILM ELECTRONIC MATERIALS U.S.A., INC., North Kingstown, RI (US)

(21) Appl. No.: 18/356,486

(22) Filed: Jul. 21, 2023

Related U.S. Application Data
(60) Provisional application No. 63/392,173, filed on Jul. 26, 2022.

(51) Int. Cl. C11D 11/00; C11D 1/02; C11D 3/00; C11D 3/33; C11D 3/30; C11D 3/28; C11D 3/39; H01L 21/306

(52) U.S. Cl. CPC C11D 11/0047; C11D 1/02; C11D 3/0047; C11D 3/33; C11D 3/30; C11D 3/28; C11D 3/3942; H01L 21/30625

(57) ABSTRACT

A composition includes at least one pH adjuster, at least one chelating agent, at least one anionic surfactant, at least one nitrogen containing heterocycle, at least one alkylamine compound, and an aqueous solvent, wherein the composition has a pH of from about 7 to about 14.

### CROSS-REFERENCE TO RELATED APPLICATION

The present application claims the benefit under 35 U.S.C. § 119 of U.S. Provisional Patent Application Ser. No. 63/392,173, filed on Jul. 26, 2022, which is herein incorporated by reference.

### BACKGROUND

The semiconductor industry is continually driven to improve chip performance by further miniaturization of devices through process and integration innovations. Chemical Mechanical Polishing/Planarization (CMP) is a powerful technology as it makes many complex integration schemes at the transistor level possible, thereby facilitating increased chip density.

CMP is a process used to planarize/flatten a wafer surface by removing material using abrasion-based physical processes concurrently with surface-based chemical reactions. In general, a CMP process involves applying CMP slurry (e.g., an aqueous chemical formulation) to a wafer surface while contacting the wafer surface with a polishing pad and moving the polishing pad in relation to the wafer. CMP slurries typically include an abrasive component and dissolved chemical components, which can vary significantly depending upon the materials present on the wafer (e.g., metals, metal oxides, metal nitrides, dielectric materials such as silicon oxide, silicon nitride, etc.) that will be interacting with the slurry and the polishing pad during the CMP process.

After CMP processing, the polished wafers are usually rinsed with deionized water, commonly referred to as high pressure rinsing, to terminate any chemical reactions and remove water miscible components (e.g., pH adjusters, organic components, and oxidants) and byproducts (e.g., ionic metals removed during CMP or pad debris) left on the polished wafer after the CMP processing step. However, even after the deionized water rinse, a variety of contaminants may remain on the surface of the polished wafer. Contaminants may include, for example, particulate abrasive from the CMP slurry, organic residue from the pad or slurry components, and material removed from the wafer during the CMP process. If left on the surface of the polished wafer, these contaminants may lead to failures during further wafer processing steps and/or to diminished device performance. Thus, the contaminants need to be effectively removed so that the polished wafer may predictably undergo further processing and/or to achieve optimal device performance.

Commonly, the process of removing these post-polishing contaminants or residues on the wafer surface after CMP (and the deionized water rinse) is performed with post-CMP (P-CMP) cleaning solutions. P-CMP cleaning solutions are applied to the polished wafer using a brush scrubber or a spin rinse dry apparatus (i.e., the wafer is removed from the CMP polishing tool and transferred to a different apparatus for P-CMP cleaning). Nonetheless, with the complex integration schemes and scaling down of size in advanced node semiconductor manufacturing, it has been increasingly noticed that traditional P-CMP cleaning is insufficient to adequately remove contaminants from the polished wafer.

### SUMMARY

In semiconductor chip manufacturing, defectivity on the wafer surface is the key to the yield of the wafers which determines the top and bottom line of chip companies globally. A typical wafer goes through about 1000 processes before chips are made and the individual dies are cut from the wafer. At each of these processes, the defectivity is monitored pre- & post-process. CMP is an important step in chip manufacturing. However, the CMP steps introduce a significant amount of defects to the wafers. As mentioned above, the conventional workflow, shown in FIG. 1, has proven inadequate at removing contaminants in advanced node semiconductor manufacturing. The present disclosure relates to polisher rinse compositions and methods for processing a polished substrate on the polishing tool itself (i.e., without removing the polished substrate from the polishing tool). A general workflow for a method using polisher rinse compositions according to this disclosure is shown in FIG. 2 and will be described in detail later in this disclosure. Thus, the present disclosure discusses polisher rinse compositions and methods which not only reduce wafer defects but also provide various other electrochemical attributes that are critical for chip manufacturing.

In one aspect, this disclosure features a composition that includes at least one pH adjuster; at least one chelating agent; at least one anionic surfactant; at least one nitrogen containing heterocycle; at least one alkylamine compound; and an aqueous solvent; in which the composition has a pH of from about 7 to about 14.

In another aspect, the disclosure features a composition that includes at least one organic base; at least one amino acid; at least one nitrogen containing heterocycle; at least one anionic surfactant; at least one compound including one amine group and a linear, branched or cyclic alkyl group; and an aqueous solvent, in which the composition has a pH of from about 7 to about 14.

In still another aspect, this disclosure features a method that includes applying the composition disclosed (e.g., a polisher rinse composition) to a polished substrate containing cobalt or an alloy thereof on a surface of the substrate in a polishing tool; and bringing a pad into contact with the surface of the substrate and moving the pad in relation to the substrate to form a rinse polished substrate.

This summary is provided to introduce a selection of concepts that are further described below in the detailed description. This summary is not intended to identify key or essential features of the claimed subject matter, nor is it intended to be used as an aid in limiting the scope of the claimed subject matter.

### DESCRIPTION OF DRAWINGS

FIG. 1 is a workflow diagram for a conventional CMP and P-CMP clean process.

FIG. 2 is a workflow diagram for an example of CMP and, optionally, a P-CMP clean process that incorporates a rinse composition described herein after the CMP process.

### DETAILED DESCRIPTION

Embodiments disclosed herein relate generally to rinse compositions and methods of using said compositions to wash substrates while the substrates are still on a polishing tool (e.g., a CMP polishing tool). In particular, the rinse compositions can be used to clean substrates directly after a CMP process and these rinse compositions are sometimes referred to herein as “rinse polish”, “buff chemical”, or “polisher rinse” compositions. In addition, the rinse compositions described herein can also find use in removing residue and/or contaminants from a substrate surface after an etching process, after an ashing process, after a plating process, or even in a conventional P-CMP cleaning process (i.e., one that takes place using a separate apparatus from the polishing tool).

As defined herein, residue and/or contaminants can include components present in a CMP polishing composition that has been used to polish the substrate to be cleaned (e.g., abrasives, molecular components, polymers, acids, bases, salts, surfactants, etc.), compounds produced during the CMP process as a result of chemical reactions between the substrate and the polishing composition and/or between components of the polishing composition, polishing pad debris particles (e.g., particles of a polymeric pad), polishing byproducts, organic or inorganic residues (e.g., those from a CMP slurry or CMP pad), substrate (or wafer) particles liberated during the CMP process, and/or any other removable materials that are known to deposit on a substrate after a CMP process.

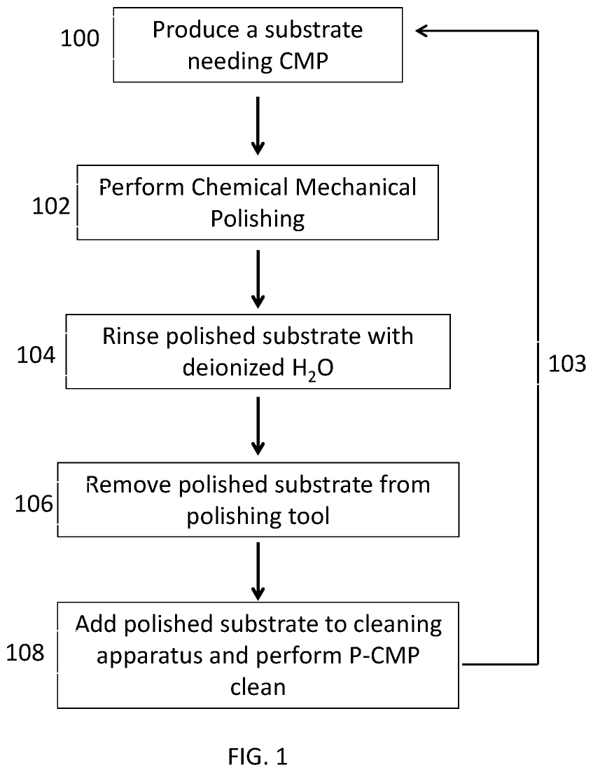

FIG. 1 is a workflow diagram for a conventional CMP and P-CMP clean process. The CMP step is typically performed in a polishing tool, which includes at least a polishing chamber (which includes polishing pads, polishing platens, and polishing heads), a cleaning chamber, and a drying chamber. In step 100, a substrate needing CMP is produced, e.g., after lithography and/or after a material is deposited on the substrate. For example, the material that is deposited can be a metal or a dielectric material and the substrate can be a silicon wafer. In step 102, chemical mechanical planarization is performed in a polishing chamber of a polishing tool. For example, a wafer can be delivered to a polishing head in the polishing chamber and attached to the polishing head by vacuum before the CMP. The head can then bring the wafer to press onto a polishing pad, rotate the wafer, and apply an appropriate pressure to the wafer during CMP. CMP is performed in order to remove unnecessary deposited material and planarize the surface of the deposited material on the substrate. After the CMP, in step 104 the polished substrate (where “polished substrate” is defined as a substrate that has been polished using a CMP method) is rinsed with deionized (DI) water. This step is commonly believed to assist in washing/cleaning debris and residue left on the polished substrate and takes place in the polishing chamber of the polishing tool using milder polishing conditions (e.g., less downforce and rotational speed) directly after the polishing. However, without wishing to be bound by theory, it is believed that the drastic pH change from a CMP polishing composition (which can be highly acidic or highly alkaline) to DI water can cause some adverse chemistry to occur that can effectively cause a portion of the debris/residue to stick more tightly to the polished substrate surface. Subsequently, the now more tightly bound debris/residue are much more difficult to remove with the conventional P-CMP cleaning process once the polished substrate is removed from the polishing tool 106, transferred to a conventional P-CMP cleaning apparatus and cleaned 108. In some embodiments, a conventional P-CMP cleaning step can include a P-CMP composition containing a pH adjuster, a corrosion inhibitor, and water. In some embodiments, a conventional P-CMP composition does not include an oxidizer. Optionally, after the conventional P-CMP cleaning in step 108, the polished substrate can be subjected to workflow 103 during which steps 100, 102, 104, 106, and 108 are repeated. If no further lithography/deposition and CMP is desired after step 108, the polished substrate can be used in a subsequent semiconductor manufacturing process.

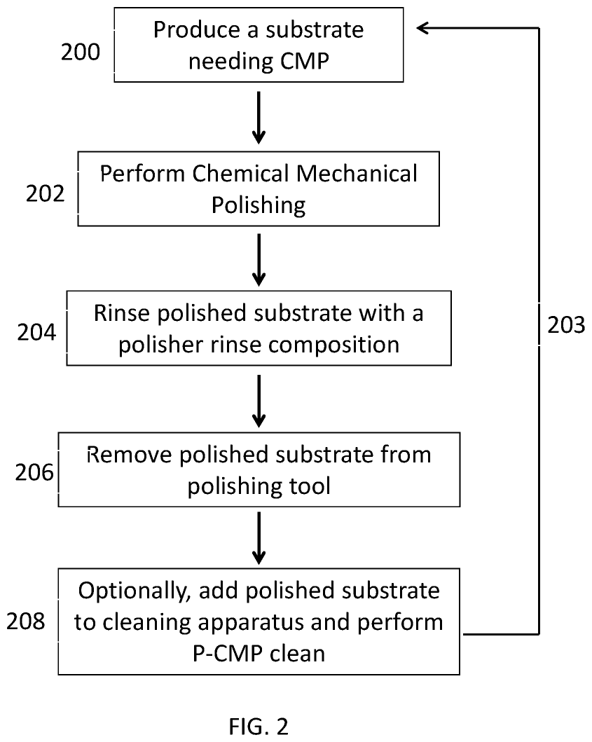

FIG. 2 is a workflow diagram for an example of a process of the present invention, which incorporates a polisher rinse composition described herein between the CMP process and an optional P-CMP process. In step 200, a substrate needing CMP is produced, e.g., after lithography and/or after deposition of a material on the substrate. In step 202, chemical mechanical planarization is performed in a polishing chamber of a polishing tool. After the CMP, in step 204, the polished substrate is rinsed with a polisher rinse composition as disclosed herein. In some embodiments, a brief (e.g., a few seconds or less) DI water rinse is applied to the polished substrate directly after CMP. This brief DI water rinse can purge the equipment lines, the pad, and the polished substrate of any remaining CMP polishing composition and wash away any large debris. As mentioned herein, the process in step 204 is also referred to as a “rinse polishing process”. The rinse in step 204 is performed on the polished substrate while the polished substrate is still located in the polishing chamber of the polishing tool (e.g., attached to a polishing head in the polishing chamber and facing a polishing pad). In some embodiments, the rinse of step 204 takes place immediately or shortly after the CMP of step 202. The amount of time between steps 202 and 204 can be one minute or less. In some embodiments, in step 204, the polisher rinse composition is applied to the polished substrate at the same time that the polishing pad is in contact with the polished substrate and moving in relation to the substrate (i.e., the polishing pad is being used as it would be during a CMP process).

One of the main differences between a CMP step and the rinse polish in step 204 is that the polisher rinse composition being applied to the substrate includes substantially no abrasive particles, or a much smaller amount of abrasive particles (detailed below), than a CMP slurry composition would include. Thus, the material removed from the polished substrate in step 204 is primarily the debris/residue from the polishing step and not the deposited substrate material that is intended to be maintained on the polished substrate.

In some embodiments, the polisher rinse composition used on the polished substrate has a difference in pH value that is no more than about ±3 (e.g., no more than about ±2.5, no more than about ±2, no more than about ±1.5, no more than about ±1, or no more than about ±0.5) from the pH value of the CMP composition used to polish the polished substrate. In some embodiments, the pH value of the polisher rinse composition can be acidic if the pH value of the CMP composition used to polish the substrate was acidic or the pH value of the polisher rinse composition can be basic if the pH value of the CMP composition used to polish the substrate was basic. In some embodiments, the pH value of the polisher rinse composition can be substantially the same as the pH value of the CMP polishing slurry used to polish the polished substrate. Without being bound by theory, it is believed that the use of a similar pH value for the CMP polish composition and the polisher rinse composition can result in more effective removal of the debris/residue left behind on the polished substrate than using DI water as a rinse.

The rinsed polished substrate is removed from the polishing tool in step 206 and transferred to a cleaning apparatus for the conventional (and optional) P-CMP cleaning in step 208. Optionally, after the conventional P-CMP cleaning in step 208, the polished substrate can be subjected to workflow 203 during which steps 200, 202, 204, 206, and 208 are repeated. If no further deposition and CMP is desired after step 208, the polished substrate can be used in a subsequent semiconductor manufacturing process.

In one or more embodiments, a polisher rinse composition described includes at least one pH adjuster; at least one chelating agent; at least one anionic surfactant; at least one nitrogen containing heterocycle; at least one alkylamine compound; and an aqueous solvent. In one or more embodiments, a polisher rinse composition of the present disclosure can include from about 0.01% to about 10% by weight of the at least one pH adjuster, from about 0.01% to about 10% by weight of the at least one chelating agent, from about 0.0005% to about 0.5% by weight of the at least one anionic surfactant, from about 0.0005% to about 0.5% by weight of the at least one nitrogen containing heterocycle, from about 0.0005% to about 0.5% by weight of the at least one alkylamine compound, and the remaining percent by weight (e.g., from about 80% to about 99.99% by weight) of aqueous solvent (e.g., deionized water).

In one or more embodiments, the present disclosure provides for a concentrated polisher rinse composition that can be diluted with water to obtain a point-of-use (POU) composition by up to a factor of 5, or up to a factor of 10, or up to a factor of 20, or up to a factor of 50, or up to a factor of 100, or up to a factor or 200, or up to a factor of 400, or up to a factor of 800, or up to a factor of 1000. In other embodiments, the present disclosure provides a point-of-use (POU) polisher rinse composition that can be used directly for rinsing substrate surfaces on a polishing tool.

In one or more embodiments, a POU polisher rinse composition can include from about 0.01% to about 1% by weight of the at least one pH adjuster, from about 0.01% to about 1% by weight of the at least one chelating agent, from about 0.0005% to about 0.05% by weight of the at least one anionic surfactant, from about 0.0005% to about 0.05% by weight of the at least one nitrogen containing heterocycle, from about 0.0005% to about 0.05% by weight of the at least one alkylamine compound, and the remaining percent by weight (e.g., from about 98% to about 99.99% by weight) of aqueous solvent (e.g., deionized water).

In one or more embodiments, a concentrated polisher rinse composition can include from about 0.1% to about 10% by weight of the at least one pH adjuster, from about 0.1% to about 10% by weight of the at least one chelating agent, from about 0.005% to about 0.5% by weight of the at least one anionic surfactant, from about 0.005% to about 0.5% by weight of the at least one nitrogen containing heterocycle, from about 0.005% to about 0.5% by weight of the at least one alkylamine compound, and the remaining percent by weight (e.g., from about 20% to about 99.99% by weight) of aqueous solvent (e.g., deionized water).

One way that the present disclosure distinguishes over current polishing and rinsing methods is that the polisher rinse composition of the present disclosure is not exclusively deionized water. In the present disclosure, the amount of deionized water in the polisher rinse composition can be at most 90% by weight, at most 92% by weight, at most 94% by weight, at most 96% by weight, at most 98% by weight, at most 99% by weight, at most 99.5% by weight, at most 99.8% by weight, and at most 99.9% by weight. The polisher rinse composition should also have at least one of the above-described components, namely pH adjuster, chelating agent, anionic surfactant, nitrogen containing heterocycle, an alkylamine compound, and aqueous solvent. In other embodiments, the polisher rinse composition should have two or more, three or more, four or more, five or more, or all six of the above-described components.

In one or more embodiments, the polisher rinse composition described herein can include at least one (e.g., two or three) pH adjuster. In one or more embodiments, the polisher rinse composition described herein can include a single pH adjuster. In some embodiments, the at least one pH adjuster is selected from the group consisting of ammonium hydroxide, sodium hydroxide, potassium hydroxide, cesium hydroxide, monoethanolamine, diethanolamine, triethanolamine, methylethanolamine, methyldiethanolamine, tetrabutylammonium hydroxide, tetrapropylammonium hydroxide, tetraethylammonium hydroxide, tetramethylammonium hydroxide, ethyltrimethylammonium hydroxide, diethyldimethylammonium hydroxide, dimethyldipropylammonium hydroxide, benzyltrimethylammonium hydroxide, tris(2-hydroxyethyl)methylammonium hydroxide, choline hydroxide, and any combinations thereof. In one or more embodiments, the polisher rinse composition described herein can include a single pH adjuster from the preceding group. In one or more embodiments, the pH adjuster is an organic base. Without being bound by theory, it is believed that organic base pH adjusters can provide better cleaning efficiency, while effectively avoiding metal ion (e.g., Na or K) contamination when compared with inorganic pH adjusters.

In one or more embodiments, the pH adjuster is included in the polisher rinse composition in an amount from about 0.01% to about 10% by weight of the composition. For example, the pH adjuster can be at least about 0.01% (e.g., at least about 0.02%, at least about 0.05%, at least about 0.1%, at least about 0.2%, at least about 0.5%, at least about 1%, at least about 2%, or at least about 5%) by weight to at most about 10% (e.g., at most about 5%, at most about 2%, at most about 1%, at most about 0.5%, at most about 0.2%, at most about 0.1%, at most about 0.05%, or at most about 0.02%) by weight of the polisher rinse composition described herein.

In one or more embodiments, the polisher rinse composition described herein can include at least one (e.g., two or three) chelating agent. In one or more embodiments, the polisher rinse composition described herein can include a single chelating agent. In one or more embodiments, the chelating agent selected from the group consisting of gluconic acid, lactic acid, citric acid, tartaric acid, malic acid, glycolic acid, malonic acid, formic acid, oxalic acid, acetic acid, propionic acid, peracetic acid, succinic acid, amino acetic acid, phenoxyacetic acid, bicine, diglycolic acid, glyceric acid, glycine, tricine, alanine, histidine, valine, phenylalanine, proline, glutamine, aspartic acid, glutamic acid, arginine, lysine, tyrosine, benzoic acid, ammonia, 1,2-ethanedisulfonic acid, 4-amino-3-hydroxy-1-naphthalenesulfonic acid, 8-hydroxyquinoline-5-sulfonic acid, aminomethanesulfonic acid, benzenesulfonic acid, hydroxylamine O-sulfonic acid, methanesulfonic acid, m-xylene-4-sulfonic acid, poly(4-styrenesulfonic acid), polyanetholesulfonic acid, p-toluenesulfonic acid, trifluoromethane-sulfonic acid, salts thereof, and mixtures thereof. In one or more embodiments, the polisher rinse composition described herein can include a single chelating agent from the preceding group. In one or more embodiments, the chelating agent is an amino acid. Without being bound by theory, it is believed that the chelating agent, in particular amino acids, can effectively solubilize and remove Co/Co-oxide particles at the wafer surface, while also minimizing corrosion of the wafer surface.

In one or more embodiments, the chelating agent is included in the polisher rinse composition in an amount from about 0.01% to about 10% by weight of the composition. For example, the chelating agent can be at least about 0.01% (e.g., at least about 0.02%, at least about 0.05%, at least about 0.1%, at least about 0.2%, at least about 0.5%, at least about 1%, at least about 2%, or at least about 5%) by weight to at most about 10% (e.g., at most about 5%, at most about 2%, at most about 1%, at most about 0.5%, at most about 0.2%, at most about 0.1%, at most about 0.05%, or at most about 0.02%) by weight of the polisher rinse composition described herein.

In one or more embodiments, the polisher rinse composition described herein can include at least one (e.g., two or three) anionic surfactant. In one or more embodiments, the polisher rinse composition described herein can include a single anionic surfactant. In one or more embodiments, the anionic surfactant comprises one or more phosphate groups and one or more of the following groups: a six to twenty four (24) carbon alkyl chain, from zero to eighteen (18) ethylene oxide (EO) groups, or a combination thereof. In one or more embodiments, the alkyl chain in the anionic surfactant can have at least eight carbons, at least ten carbons, at least twelve carbons, or at least fourteen carbons. In one or more embodiments, the alkyl chain in the anionic surfactant can have at most 22 carbons, or at most 20 carbons, or at most 18 carbons. In one or more embodiments, the anionic surfactant can include at least one EO group, at least two EO groups, at least three EO groups, at least four EO groups, at least five EO groups, or at least six EO groups. In one or more embodiments, the anionic surfactant can include at most fourteen EO groups, at most twelve EO groups, at most ten EO groups, at most eight EO groups, at most six EO groups, at most four EO groups, or at most two EO groups. In one or more embodiments, the polisher rinse composition described herein can include a single anionic surfactant having the preceding carbon or EO characteristics. Without wishing to be bound by theory, it is surprising that an anionic surfactant (such as those described above) can be used as a cobalt corrosion inhibitor in the polishing composition described herein to reduce or minimize the corrosion/removal rate of cobalt in a semiconductor substrate.

In some embodiments, the anionic surfactant is in an amount of from about 0.0005% to about 0.5% by weight of the polisher rinse composition described herein. For example, the anionic surfactant can be at least about 0.0005% (e.g., at least about 0.001%, at least about 0.002% at least about 0.005%, at least about 0.01%, at least about 0.05%, at least about 0.1%, or at least about 0.2%) by weight to at most about 0.5% (e.g., at most about 0.2%, at most about 0.1% at most about 0.05%, at most about 0.02%, at most about 0.01%, at most about 0.005%, at most about 0.002%, or at most about 0.001%) by weight of the polisher rinse composition described herein.

In one or more embodiments, the polisher rinse composition described herein can include at least one (e.g., two or three) nitrogen containing heterocycle. In one or more embodiments, the polisher rinse composition described herein can include a single nitrogen containing heterocycle. In one or more embodiments, the nitrogen containing heterocycle contains at least two (e.g., three or four) ring nitrogen atoms. In one or more embodiments, the nitrogen containing heterocycle is an azole, such as a triazole (e.g., a benzotriazole), a tetrazole, a pyrazole, an imidazole, or a thiadiazole, each of which is optionally substituted with one or more substituents (e.g., halo, amino, C₁-C₁₀ alkyl, C₁-C₁₀ arylalkyl, C₁-C₁₀ haloalkyl, or aryl). In one or more embodiments, the nitrogen containing heterocycle is a purine (e.g., 9H-purine, xanthine, hypoxanthine, guanine, and isoguanine) or a pyrimidine (e.g., cytosine, thymine, and uracil). In one or more embodiments, the nitrogen containing heterocycle is selected from the group consisting of tetrazole, benzotriazole, tolyltriazole, methyl benzotriazole (e.g., 1-methyl benzotriazole, 4-methyl benzotriazole, and 5-methyl benzotriazole), ethyl benzotriazole (e.g., 1-ethyl benzotriazole), propyl benzotriazole (e.g., 1-propyl benzotriazole), butyl benzotriazole (e.g., 1-butyl benzotriazole and 5-butyl benzotriazole), pentyl benzotriazole (e.g., 1-pentyl benzotriazole), hexyl benzotriazole (e.g., 1-hexyl benzotriazole and 5-hexyl benzotriazole), dimethyl benzotriazole (e.g., 5,6-dimethyl benzotriazole), chloro benzotriazole (e.g., 5-chloro benzotriazole), dichloro benzotriazole (e.g., 5,6-dichloro benzotriazole), chloromethyl benzotriazole (e.g., 1-(chloromethyl)-1-H-benzotriazole), chloroethyl benzotriazole, phenyl benzotriazole, benzyl benzotriazole, aminotriazole, aminobenzimidazole, pyrazole, imidazole, aminotetrazole, adenine, xanthine, cytosine, thymine, uracil, 9H-purine, guanine, isoguanine, hypoxanthine, benzimidazole, thiabendazole, 1,2,3-triazole, 1,2,4-triazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, and combinations thereof. In one or more embodiments, the polisher rinse composition described herein can include a single a single nitrogen containing heterocycle from the preceding group. In one or more embodiments, the nitrogen containing heterocycle is chemically distinct from the chelating agent.

In some embodiments, the nitrogen containing heterocycle is in an amount of from about 0.0005% to about 0.5% by weight of the polisher rinse composition described herein. For example, the nitrogen containing heterocycle can be at least about 0.0005% (e.g., at least about 0.001% at least about 0.002%, at least about 0.005%, at least about 0.01%, at least about 0.05%, at least about 0.1%, or at least about 0.2%) by weight to at most about 0.5% (e.g., at most about 0.2% at most about 0.1%, at most about 0.05%, at most about 0.02%, at most about 0.01%, at most about 0.005%, at most about 0.002%, or at most about 0.001%) by weight of the polisher rinse composition described herein.

In one or more embodiments, an optional secondary solvent (e.g., an organic solvent) can be used in the polishing composition (e.g., the POU or concentrated polishing composition) of the present disclosure, which can help with the dissolution of certain components (e.g., nitrogen containing heterocycle, alkylamine, etc.) of the polisher rinse composition. In one or more embodiments, the secondary solvent can be one or more alcohols, alkylene glycols, or alkylene glycol ethers. In one or more embodiments, the secondary solvent comprises one or more solvents selected from the group consisting of ethanol, 1-propanol, 2-propanol, n-butanol, propylene glycol, 2-methoxyethanol, 2-ethoxyethanol, propylene glycol propyl ether, and ethylene glycol.

In some embodiments, the secondary solvent is in an amount of from at least about 0.005% (e.g., at least about 0.01%, at least about 0.02%, at least about 0.05%, at least about 0.1% at least about 0.2%, at least about 0.4%, at least about 0.6%, at least about 0.8%, at least about 1%, at least about 3%, at least about 5%, or at least about 10%) by weight to at most about 15% (e.g., at most about 12%, at most about 10%, at most about 5%, at most about 3%, at most about 2%, at most about 1%, at most about 0.8%, at most about 0.6%, at most about 0.5%, or at most about 0.1%) by weight of the polishing composition described herein.

In one or more embodiments, the polishing compositions described herein include at least one (e.g., two or three) alkylamine compound. In one or more embodiments, the polisher rinse composition described herein can include a single alkylamine compound. In one or more embodiments, the alkylamine compound can include only one amine group. In one or more embodiments, the alkylamine compound can include one amine group and a linear, branched, or cyclic alkyl group. In one or more embodiments, the alkylamine compound can be an alkylamine compound that has at least one (e.g., two or three) alkyl chain that includes between 6 and 24 (i.e., 6, 7, 8, 9, 10, 11, 12, 13, 14, 15, 16, 17, 18, 19, 20, 21, 22, 23, or 24) carbons. In one or more embodiments, the alkyl chain can be a linear, branched, or cyclic alkyl group. In one or more embodiments, the alkylamine compound can be a primary amine, secondary amine, tertiary amine, or cyclic amine compound. In one or more embodiments, the polisher rinse composition described herein can include a single alkylamine from the preceding group. In one or more embodiments, the alkylamine compound is chemically distinct from the chelating agent and/or the nitrogen containing heterocycle component described above. In one or more embodiments, the alkylamine compound can be an alkoxylated amine (e.g., include ethoxylate and/or propoxylate groups). In one or more embodiments, the alkoxylated amine can include from 2 to 100 ethoxylate and/or propoxylate groups. In some embodiments, the at least one alkylamine compound has an alkyl chain that includes between 6 and 18 carbons. In some embodiments, the alkylamine is selected from the group consisting of hexylamine, octylamine, decylamine, dodecylamine, tetradecylamine, pentadecylamine, hexadecylamine, octadecylamine, cyclohexylamine, dicyclohexylamine, or mixtures thereof. Without wishing to be bound by theory, it is surprising that the alkylamine compounds described above can significantly reduce or minimize the corrosion or etching of tungsten and/or its alloys in a semiconductor substrate.

In some embodiments, the alkylamine compound is in an amount of from about 0.0005% to about 0.5% by weight of the polisher rinse composition described herein. For example, the alkylamine compound can be at least about 0.0005% (e.g., at least about 0.001%, at least about 0.002% at least about 0.005%, at least about 0.01%, at least about 0.05%, at least about 0.1%, or at least about 0.2%) by weight to at most about 0.5% (e.g., at most about 0.2%, at most about 0.1% at most about 0.05%, at most about 0.02%, at most about 0.01%, at most about 0.005%, at most about 0.002%, or at most about 0.001%) by weight of the polisher rinse composition described herein.

An optional oxidizer can be added when diluting a concentrated polisher rinse composition to form a POU slurry. The oxidizer can be selected from the group consisting of hydrogen peroxide, ammonium persulfate, silver nitrate (AgNO₃), ferric nitrates or chlorides, per acids or salts, ozone water, potassium ferricyanide, potassium dichromate, potassium iodate, potassium bromate, potassium periodate, periodic acid, vanadium trioxide, hypochlorous acid, sodium hypochlorite, potassium hypochlorite, calcium hypochlorite, magnesium hypochlorite, ferric nitrate, potassium permanganate, other inorganic or organic peroxides, and mixtures thereof. In one embodiment, the oxidizer is hydrogen peroxide.

In some embodiments, the oxidizer is in an amount of from at least about 0.05% (e.g., at least about 0.1%, at least about 0.2%, at least about 0.4%, at least about 0.5%, at least about 1%, at least about 1.5%, at least about 2%, at least about 2.5%, at least about 3%, at least about 3.5%, at least about 4%, or at least about 4.5%) by weight to at most about 5% (e.g., at most about 4.5%, at most about 4%, at most about 3.5%, at most about 3%, at most about 2.5%, at most about 2%, at most about 1.5%, at most about 1%, at most about 0.5%, or at most about 0.1%) by weight of the polisher rinse composition described herein. In some embodiments, without wishing to be bound by theory, it is believed that the oxidizer can help passivate a metal surface by forming an oxide film that can increase the corrosion resistance of the metal film. In some embodiments, the oxidizer may reduce the shelf life of a polisher rinse composition. In such embodiments, the oxidizer can be added to the polisher rinse composition at the point of use right before a rinse polishing process.

The pH for the polisher rinse compositions of the present disclosure are alkaline because cobalt is too readily corroded in acidic pH, while in alkaline pH surface oxides can be formed on cobalt films, which can mitigate dissolution. In some embodiments, the pH value of the polisher rinse composition described herein can range from at least about 7 (e.g., at least about 7.5, at least about 8, at least about 8.5, at least about 9, at least about 9.5, at least about 10, at least about 10.5, at least about 11, or at least about 11.5) to at most about 14 (e.g., at most about 13.5, at most about 13, at most about 12.5, at most about 12, at most about 11.5, at most about 11, at most about 10.5, at most about 10, at most about 9.5, at most about 9, or at most about 8.5). In more specific embodiments where cobalt and tungsten surfaces will interface with the polisher rinse composition it may be beneficial to keep the pH below 9 for potential corrosion reduction.

In one or more embodiments, the polisher rinse composition described herein can optionally include a relatively small amount of abrasive particles. In some embodiments, the abrasive particles can include silica, ceria, alumina, titania, and zirconia abrasives. In some embodiments, the abrasive particles can include non-ionic abrasives, surface modified abrasives, or negatively/positively charged abrasives. In some embodiments, the polisher rinse composition can include abrasive particles in an amount of from at least 0.001% (e.g., at least about 0.005%, at least about 0.01%, at least about 0.05%, or at least about 0.1%) by weight to at most about 0.2% (e.g., at most about 0.15%, at most about 0.1%, at most about 0.05%, or at most about 0.01%) by weight of the polisher rinse composition described herein.

In one or more embodiments, the composition is substantially free of abrasive particles. As used herein, an ingredient that is “substantially free” from a composition refers to an ingredient that is not intentionally added into the cleaning composition. In some embodiments, the composition described herein can have at most about 2000 ppm (e.g., at most about 1000 ppm, at most about 500 ppm, at most about 250 ppm, at most about 100 ppm, at most about 50 ppm, at most about 10 ppm, or at most about 1 ppm) of abrasive particles. In some embodiments, the composition described herein can be completely free of abrasive particles.

In one or more embodiments, the polishing composition described herein can be substantially free of one or more of certain ingredients, such as organic solvents, pH adjusting agents, tetramethylammonium hydroxide, alkali bases (such as alkali hydroxides), fluorine-containing compounds (e.g., fluoride compounds or fluorinated compounds (such as fluorinated polymers/surfactants)), silicon-containing compounds such as silanes (e.g., alkoxysilanes), nitrogen containing compounds (e.g., amino acids, amines, or imines (e.g., amidines such as 1,8-diazabicyclo[5.4.0]-7-undecene (DBU) and 1,5-diazabicyclo[4.3.0]non-5-ene (DBN)), amides, or imides), salts (e.g., halide salts or metal salts), polymers (e.g., non-ionic, cationic, anionic, or water-soluble polymers), inorganic acids (e.g., hydrochloric acid, sulfuric acid, phosphoric acid, or nitric acid), surfactants (e.g., cationic surfactants, anionic surfactants, non-polymeric surfactants, or non-ionic surfactants), plasticizers, oxidizing agents (e.g., hydrogen peroxide and periodic acid), corrosion inhibitors (e.g., azole or non-azole corrosion inhibitors), electrolytes (e.g., polyelectrolytes), and/or certain abrasives (e.g., polymeric abrasives, fumed silica, ceria abrasives, non-ionic abrasives, surface modified abrasives, negatively/positively charged abrasives, or ceramic abrasive composites). The halide salts that can be excluded from the polishing compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a polishing composition refers to an ingredient that is not intentionally added into the polishing composition. In some embodiments, the polishing composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above ingredients that are substantially free from the polishing composition. In some embodiments, the polishing compositions described herein can be completely free of one or more of the above ingredients.

As applied to polisher rinse operations, the polisher rinse compositions described herein are usefully employed to remove contaminants present on a substrate surface directly after a CMP processing step while the polished substrate is still located within the polishing chamber of the polishing tool. In one or more embodiments, the contaminants can be at least one selected from the group consisting of abrasives, particles, organic residues, polishing byproducts, slurry byproducts, slurry induced organic residues, and inorganic polished substrate residues. In one or more embodiments, the polisher rinse compositions of the present disclosure can be employed to remove organic residues containing organic particles which are insoluble in water and thus remain on the wafer surface post the CMP polishing step. Without being bound by theory, it is believed that the organic particles can be generated from CMP polishing composition components that deposit on a substrate surface after polishing and are insoluble and thus stick as contaminants on the wafer surface. The presence of the contaminants described above results in defect counts on the wafer surface. These defect counts, when analyzed on a defect measuring tool such as the AIT-XUV tool from KLA Tencor Company, provide the total defect count (TDC) that is a sum of all the individual defect counts. In one or more embodiments, the compositions described herein remove at least about 30% (e.g., at least about 50%, at least about 75%, at least about 80%, at least about 90%, at least about 95%, at least about 98%, at least about 99%, at least about 99.5%, at least about 99.9%) of the total defect count (TDC) remaining on a substrate surface after a polishing/CMP process.

In some embodiments, this disclosure features a method of rinse polishing a previously polished substrate (e.g., a wafer polished by a CMP composition). The method can include contacting, within a polishing tool, the polished substrate with a polisher rinse composition described herein. In some embodiments, the substrate described herein (e.g. a wafer) can include at least one material selected from the group consisting of tungsten, titanium nitride, silicon carbide, silicon oxide (e.g., TEOS), low-K and ultra low-k materials (e.g., doped silica and amorphous carbon), silicon nitride, copper, cobalt, ruthenium, molybdenum, and polysilicon on a substrate surface.

In rinse polishing operations, the polisher rinse composition can be applied to the polished substrate in the same way that a CMP composition would have been applied to the previously polished substrate (e.g., the polisher rinse composition is applied while the polished substrate is in contact with a polishing pad). In some embodiments, the conditions can be milder during a rinse polishing process than the conditions used during a CMP process. For example, the down force, rotational speed, or time in a rinse polishing process can be less than the same conditions used in the prior CMP process.

In some embodiments, the down force used in a rinse polishing process is from at least about 5% (e.g., at least about 10%, at least about 15%, at least about 20%, at least about 25%, at least about 30%, at least about 35%, at least about 40%, at least about 45%, at least about 50%, at least about 55%, at least about 60%, at least about 65%, at least about 70%, or at least about 75%) to at most about 90% (e.g., at most about 85%, at most about 80%, at most about 75%, at most about 70%, or at most about 65%) of the down force used in a CMP process (e.g., in a preceding CMP process). In one or more embodiments, the down force used in a CMP process is from about 1 psi to about 4 psi. In some embodiments, a polishing pad is brought into contact with the previously polished substrate, but substantially no down force is applied to the previously polished substrate during the rinse polishing process. In some embodiments, the down force used in a rinse polishing process is substantially the same as the down force used in the prior CMP operation.

In some embodiments, the time used in a rinse polishing process is from at least about 10% (e.g., at least about 15%, at least about 20%, at least about 25%, at least about 30%, or at least about 35%) to at most about 50% (e.g., at most about 45%, at most about 40%, at most about 35%, at most about 30%, or at most about 25%) of the time used in a CMP process (e.g., in a preceding CMP process). In one or more embodiments, the rinse time used in a CMP process is from about 2 seconds to about 20 seconds. In some embodiments, the time used in a rinse polishing process is substantially the same as the down force used in the prior CMP operation.

In some embodiments, the polisher rinse composition described herein can be used as a post-CMP cleaner in a post-CMP cleaning step 208 (i.e., a cleaning step that takes place on a cleaning apparatus different from the polishing tool). In post-CMP cleaning applications, the polisher rinse composition can be applied in any suitable manner to the substrate to be cleaned. For example, the composition can be used with a large variety of conventional cleaning tools and techniques (e.g., brush scrubbing, spin rinse dry, etc.). In some embodiments, a cleaning tool or apparatus suitable for a post-CMP cleaning process is a tool (e.g., a brush scrubber or a spin rinse dryer) without a polishing equipment (e.g., a polishing pad, a polishing platen, and/or a polishing head). In some embodiments, the substrate to be cleaned (e.g. a wafer) in the post CMP cleaning step can include at least one material selected from the group consisting of tungsten, titanium nitride, silicon carbide, silicon oxide (e.g., TEOS), silicon nitride, copper, cobalt, ruthenium, molybdenum, and polysilicon on a substrate surface.

In some embodiments, the method that uses a polisher rinse composition described herein can further include producing a semiconductor device from the substrate treated by the cleaning composition through one or more steps. For example, photolithography, ion implantation, dry/wet etching, plasma etching, deposition (e.g., PVD, CVD, ALD, ECD), wafer mounting, die cutting, packaging, and testing can be used to produce a semiconductor device from the substrate treated by the cleaning composition described herein.

### EXAMPLES

The general compositions used in the examples are shown in Table 1 below. The specific details on the differences in the compositions tested will be explained in further detail when discussing the respective examples.

TABLE 1

| | % By Weight of the |
|---|---|
| Component | Composition |
| pH adjuster (organic base) | 0.01-1 |
| Chelating Agent (amino acid) | 0.01-1 |
| Alkylamine (including a linear 6-24 | 0.005-0.1 |
| carbon alkyl group) | (if used) |
| Anionic Surfactant | 0.005-0.1 |
| Nitrogen Containing Heterocycle (Azole) | 0.005-0.1 |
| Solvent (DI Water) | ~98-99.9 |
| | (remainder) |
| Oxidizer (H₂O₂) | 0.01-1 |
| pH | 7-10 |

### Example 1

In this example Polisher Rinse (PR) compositions 1-3 were evaluated for their ability to influence Co₃O₄ particle dissolution. PR composition 1-3 were formulated with exactly the same components and only differed in that they included differing amounts of the amino acid chelating agent. The test was performed by incubating 50 mg of cobalt oxide particles in the indicated polisher rinse composition at ambient temperature for 10 minutes under stirring. A sample of the supernatant was then taken and ppb Co was measured via ICP-MS. The results of this test are summarized in Table 2 below.

TABLE 2

| | | Dissolved Co |
|---|---|---|
| | Chelating | Ion |
| | Agent | Concentration |
| | Concentration | (ppb) |
| Polisher Rinse 1 | 7.5x | 370 |
| Polisher Rinse 2 | 10x | 420 |
| Polisher Rinse 3 | 12.5x | 470 |

The results show that the chelating agent increases the dissolved Co Ion concentration as the concentration is increased, indicating that the composition is able to dissolve particulate or residual oxides from wafter surfaces.

### Example 2

In this example Polisher Rinse (PR) compositions 4-6 were evaluated for their corrosivity towards cobalt films by measuring their static etching on a cobalt coupon. The static etching test is performed by placing a cobalt coupon into the polisher rinse composition at 60° C. for five minutes. A sample of the supernatant was then taken and the dissolved cobalt level was determined by ICP-MS. PR composition 4-6 were formulated with exactly the same components and only differed in that they included differing amounts of the anionic surfactant. The results of this test are summarized in Table 3 below.

TABLE 3

| | | Dissolved Co |
|---|---|---|
| | | Ion |
| | Anionic | Concentration |
| | Surfactant | (ppb) |
| Polisher Rinse 4 | 2x | 123 |
| Polisher Rinse 5 | 5x | 82 |
| Polisher Rinse 6 | 10x | 94 |

The results show that increasing amounts of anionic surfactant can effectively reduce cobalt corrosion. Thus, the polisher rinse composition of the present disclosure both removes and/or dissolves undesirable residue from the surface of polished wafers, and simultaneously does not adversely affect the films on the wafer.

### Example 3

In this example Polisher Rinse (PR) compositions 7-10 were evaluated for their corrosivity towards tungsten films by measuring their static etching on a tungsten coupon. The static etching test is performed by placing a tungsten coupon into the polisher rinse composition at 60° C. for five minutes. A sample of the supernatant was then taken and the dissolved tungsten level was determined by ICP-MS. PR composition 7-10 were formulated with exactly the same components and only differed in their pH and whether or not they included the alkylamine compound. The results of this test are summarized in Table 4 below.

TABLE 4

| | | | Dissolved W Ion |
|---|---|---|---|
| | | | Concentration |
| | Alkylamine | pH | (ppb) |
| Polisher Rinse 7 | No | 9 | 176 |
| Polisher Rinse 8 | Yes | 9 | 137 |
| Polisher Rinse 9 | No | 8 | 101 |
| Polisher Rinse 10 | Yes | 8 | 49 |

The results show that the addition of the alkylamine compound can effectively reduce tungsten corrosion. Additionally, the data shows that tungsten is also more protected at pH 8 than at pH 9.

### Example 4

In this example Polisher Rinse compositions 11-13 were tested for their ability to reduce defect counts on polished cobalt blanket wafers. PR composition 11-13 were formulated with exactly the same components and only differed in the amount of oxidizer used and whether an alkylamine was included.

The test was performed by initially polishing a wafer with a CMP composition to form polished wafers. The polishing was performed on 300 mm wafers using an AMAT Reflexion 300 mm CMP polisher with a Fujibo pad and a CMP slurry at a flow rate between 100 and 500 mL/min. The rinse polishing step was performed using the same pad and the same flow rate for 20 seconds following the CMP polishing. The rinse polishing step was performed using the same conditions as the preceding CMP polishing step except that the rinse polishing step used about 30% of the time of the CMP polishing step. After the rinse polishing process the wafers were removed from the polishing tool and transferred to a pCMP cleaner where they were cleaned with a conventional pCMP cleaner. The polished wafer that did not undergo rinse polishing (i.e., “No Rinse Polishing” in Table 5) was subjected to a pCMP cleaning operation directly after the initial CMP polishing process.

The compositional differences in PR compositions 11-13 and the results of the testing are summarized in Table 5 below.

| | | | Total Defect |
|---|---|---|---|
| | Alkylamine | Oxidizer | Counts (TDC) |
| No Rinse Polishing | N/A | N/A | 932 |
| Polisher Rinse 11 | No | 2x | 202 |
| Polisher Rinse 12 | No | 1x | 333 |
| Polisher Rinse 13 | Yes | 2x | 297 |

The results show that PR compositions 11-13 significantly reduced the TDC when compared with the wafer that did not undergo a rinse polishing process. Further, the amount of oxidizer and the inclusion of the alkylamine did not greatly impact the defectivity performance.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A composition, comprising:
at least one pH adjuster;
at least one chelating agent;
at least one anionic surfactant;
at least one nitrogen containing heterocycle;
at least one alkylamine compound; and
an aqueous solvent;
wherein the composition has a pH of from about 7 to about 14.

2. The composition of claim 1, wherein the at least one pH adjuster is selected from the group consisting of ammonium hydroxide, sodium hydroxide, potassium hydroxide, cesium hydroxide, monoethanolamine, diethanolamine, triethanolamine, methylethanolamine, methyldiethanolamine, tetrabutylammonium hydroxide, tetrapropylammonium hydroxide, tetraethylammonium hydroxide, tetramethylammonium hydroxide, ethyltrimethylammonium hydroxide, diethyldimethylammonium hydroxide, dimethyldipropylammonium hydroxide, benzyltrimethylammonium hydroxide, tris(2-hydroxyethyl)methylammonium hydroxide, choline hydroxide, and any combinations thereof.

3. The composition of claim 1 or 2, wherein the at least one pH adjuster is in an amount of from about 0.01% to about 10% by weight of the composition.

4. The composition of any of claims 1-3, wherein the at least one chelating agent can be selected from the group consisting of gluconic acid, lactic acid, citric acid, tartaric acid, malic acid, glycolic acid, malonic acid, formic acid, oxalic acid, acetic acid, propionic acid, peracetic acid, succinic acid, amino acetic acid, phenoxyacetic acid, bicine, diglycolic acid, glyceric acid, glycine, tricine, alanine, histidine, valine, phenylalanine, proline, glutamine, aspartic acid, glutamic acid, arginine, lysine, tyrosine, benzoic acid, ammonia, 1,2-ethanedisulfonic acid, 4-amino-3-hydroxy-1-naphthalenesulfonic acid, 8-hydroxyquinoline-5-sulfonic acid, aminomethanesulfonic acid, benzenesulfonic acid, hydroxylamine O-sulfonic acid, methanesulfonic acid, m-xylene-4-sulfonic acid, poly(4-styrenesulfonic acid), polyanetholesulfonic acid, p-toluenesulfonic acid, trifluoromethane-sulfonic acid, salts thereof, and mixtures thereof.

5. The composition of any one of claims 1-4, wherein the at least one chelating agent is in an amount of from about 0.01% to about 10% by weight of the composition.

6. The composition of any of claims 1-6, wherein the at least one anionic surfactant comprises one or more phosphate groups and one or more of the following: a six to twenty four carbon alkyl chain, zero to eighteen ethylene oxide groups, or a combination of a six to twenty four carbon alkyl chain and multiple ethylene oxide groups.

7. The composition of any one of claims 1-7, wherein the at least one anionic surfactant is in an amount of from about 0.0005% to about 0.5% by weight of the composition.

8. The composition of any one of claims 1-8, wherein the at least one nitrogen containing heterocycle is selected from the group consisting of tetrazole, benzotriazole, tolyltriazole, 1-methyl benzotriazole, 4-methyl benzotriazole, 5-methyl benzotriazole, 1-ethyl benzotriazole, 1-propyl benzotriazole, 1-butyl benzotriazole, 5-butyl benzotriazole, 1-pentyl benzotriazole, 1-hexyl benzotriazole, 5-hexyl benzotriazole, 5,6-dimethyl benzotriazole, 5-chloro benzotriazole, 5,6-dichloro benzotriazole, 1-(chloromethyl)-1H-benzotriazole, chloroethyl benzotriazole, phenyl benzotriazole, benzyl benzotriazole, aminotriazole, aminobenzimidazole, pyrazole, imidazole, aminotetrazole, adenine, xanthine, cytosine, thymine, uracil, 9H-purine, guanine, isoguanine, hypoxanthine, benzimidazole, thiabendazole, 1,2,3-triazole, 1,2,4-triazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, and combinations thereof.

9. The composition of any one of claims 1-9, wherein the at least one nitrogen containing heterocycle is in an amount of from about 0.0005% to about 0.5% by weight of the composition.

10. The composition of any one of claims 1-10, wherein the alkylamine compound comprises an amino group and a 6 to 24 carbon alkyl group.

11. The composition of any one of claims 1-11, the alkylamine is selected from the group consisting of hexylamine, octylamine, decylamine, dodecylamine, tetradecylamine, pentadecylamine, hexadecylamine, octadecylamine, cyclohexylamine, dicyclohexylamine, or mixtures thereof

12. The composition of any one of claims 1-12, wherein the alkylamine compound is in an amount from about 0.0005% to about 0.5% by weight of the composition.

13. The composition of any one of claims 1-13, wherein the composition has at most about 0.2% by weight of abrasive particles.

14. The composition of any one of claims 1-14, wherein the composition is substantially free of abrasive particles.

15. A composition, comprising:
at least one organic base;
at least one amino acid;
at least one azole compound;
at least one anionic surfactant; and
at least one compound including one amine group and a linear, branched, or cyclic alkyl group;
wherein the composition has a pH of from about 7 to about 14.

16. A method, comprising:
applying a first composition that is the composition of any one of claims 1-16 to a polished substrate comprising cobalt or an alloy thereof on a surface of the substrate in a polishing tool; and
bringing a pad into contact with the surface of the polished substrate and moving the pad in relation to the substrate to form a rinse polished substrate.

17. The method of claim 17, further comprising removing the cleaned substrate from the polishing tool and performing a post-CMP cleaning on the rinse polished substrate in a cleaning tool.

18. The method of claim 18, further comprising forming a semiconductor device from the substrate.

19. The method of claim 17, further comprising the steps of, prior to the applying step:
supplying a substrate; and
polishing the substrate with a chemical-mechanical polishing composition, to form the polished substrate.

20. The method of claim 20, wherein the first composition has a first pH, and the chemical-mechanical polishing composition has a second pH, and wherein the difference in value between the first pH and the second pH is no more than about ±3.

21. The method of claim 17, wherein the first composition includes abrasives.
